(19) United States
(12) Patent Application Publication
(10) Pub. No.: US 2005/0148138 A1
(43) Pub. Date: Jul. 7, 2005

(54) Method of manufacturing semiconductor device

(76) Inventors: Takafumi Noda, Shiojiri-shi (JP); Susumu Inoue, Sakata-shi (JP); Masahiko Tsuyuki, Chino-shi (JP); Akihiko Ebina, Nagano-ken (JP)

Correspondence Address: EDWARDS & ANGELL, LLP, P.O. BOX 55874, BOSTON, MA, 02205, US

(21) Appl. No.: 10/961,767

(22) Filed: Oct. 7, 2004

(30) Foreign Application Priority Data
Oct. 10, 2003 (JP) 2003-352707

(51) Int. Cl. H01L 21/8238

(52) U.S. Cl. 438/216

(57) ABSTRACT

A method of manufacturing a semiconductor device that has a high-breakdown-voltage transistor, a low-voltage driving transistor and a MONOS type memory transistor includes a step of forming a stack film that includes at least an oxide silicon layer and a nitride silicon layer over a high-breakdown-voltage transistor forming region where the high-breakdown-voltage transistor is formed, a low-voltage driving transistor forming region where the low-voltage driving transistor is formed and a MONOS type memory transistor forming region where the MONOS type memory transistor is formed in a semiconductor layer, a step of removing the stack film formed in a first gate insulating layer forming region of the high-breakdown-voltage transistor and a step of forming a first gate insulating layer in the high-breakdown-voltage transistor forming region by thermal oxidation. The method also includes a step of removing the stack film formed in the low-voltage driving transistor forming region, a step of forming a second gate insulating layer in the low-voltage driving transistor forming region, a step of forming gate electrodes in the high-breakdown-voltage transistor forming region, the low-voltage driving transistor forming region and the MONOS type memory transistor forming region and a step of forming source/drain regions in the high-breakdown-voltage transistor forming region, the low-voltage driving transistor forming region and the MONOS type memory transistor forming region.

The present invention claim priority from Japanese Application No. 2003-352707 filed on Oct. 10, 2003, which is hereby incorporated by reference in its entirety.

### BACKGROUND OF THE INVENTION

1. Field of the Invention

The present invention relates to a method of manufacturing a semiconductor device, more particularly, the invention relates to a method of manufacturing a semiconductor device that has transistors whose gate breakdown voltage and drain breakdown voltage are different and a Metal-Nitride-Oxide-Semiconductor (MNOS) type memory transistor in the same semiconductor layer.

2. Description of the Related Art

In a process of manufacturing a high-breakdown-voltage transistor, a high temperature process compared to that of a low-voltage driving transistor is needed in order to form a deep well and a thick gate insulating layer. Such high temperature process is specific for the low-voltage driving transistor, and generally, the high-breakdown-voltage transistor for a high voltage operation and the low-voltage driving transistor are formed separately.

At the same time, so called System on Chip (SOC) technology has been developed recently. The SOC technology is a technique in which a system function that previously was realized by combining several integrated circuits (IC) can be realized in a single IC chip.

### SUMMARY OF THE INVENTION

The present invention is intended to provide a method of manufacturing a semiconductor device that has a MNOS memory transistor and a transistor whose gate breakdown voltage and drain breakdown voltage are different in the same semiconductor layer.

A method of manufacturing a semiconductor device of an embodiment of the present invention is a method of forming a transistor that has a high-breakdown-voltage transistor, a low-voltage driving transistor and a Metal-Nitride-Oxide-Semiconductor (MNOS) type memory transistor. The method includes a step of forming a stack film that includes at least an oxide silicon layer and a nitride silicon layer over a high-breakdown-voltage transistor forming region where the high-breakdown-voltage transistor is formed, a low-voltage driving transistor forming region where the low-voltage driving transistor is formed and a MNOS type memory transistor forming region where the MNOS type memory transistor is formed in a semiconductor layer, a step of removing the stack film formed in a first gate insulating layer forming region of the high-breakdown-voltage transistor and a step of forming a first gate insulating layer in the high-breakdown-voltage transistor forming region by thermal oxidation. The method also includes a step of removing the stack film formed in the low-voltage driving transistor forming region, a step of forming a second gate insulating layer in the low-voltage driving transistor forming region, a step of forming gate electrodes in the high-breakdown-voltage transistor forming region, the low-voltage driving transistor forming region and the MNOS type memory transistor forming region and a step of forming source/drain regions in the high-breakdown-voltage transistor forming region, the low-voltage driving transistor forming region and the MNOS type memory transistor forming region.

In the method of manufacturing a semiconductor device of one embodiment of the present invention, a Metal-Oxide-Nitride-Semiconductor (MNOS) type memory transistor includes a Metal-Oxide-Nitride-Oxide-Semiconductor (MONOS) type memory transistor. In other words, the stack film includes at least the oxide silicon layer and the nitride silicon layer. That is, the first oxide silicon layer, the nitride silicon layer and the second oxide silicon layer may be stacked in layers.

In the method of manufacturing a semiconductor device of an embodiment of the present invention, forming another specific layer (hereinafter called “layer B”) over a specific layer (hereinafter called “layer A”) includes a case in which the layer B is directly formed on the layer A and a case in which the layer B is formed on the layer A with at least one layer therebetween. Also, “source/drain region” means a source region and/or a drain region.

According to the above-mentioned method of manufacturing a semiconductor device of one embodiment of the present invention, the high-breakdown-voltage transistor, which requires a high temperature process compared with the low-voltage driving transistor in order to form a deep well and a thick gate insulating electrode, and the MONOS type memory transistor that requires a special stack film forming process can be provided together.

In the method of manufacturing a semiconductor device according to one embodiment of the invention, the stack film may be formed such that a first oxide silicon layer, a nitride silicon layer and a second oxide silicon layer are stacked in layers.

The method of manufacturing a semiconductor device may include a step of forming sacrificial oxide layer may be formed over the semiconductor layer before the stack film.

The method of manufacturing a semiconductor device may include a step of forming well in the low-voltage driving transistor forming region and the MONOS type memory transistor forming region before the first gate insulating layer is formed.

The method of manufacturing a semiconductor device may include a step of forming well in the low-voltage driving transistor forming region and the MONOS type memory transistor forming region after the first gate insulating layer is formed.

The method of manufacturing a semiconductor device may include a step of forming an isolation region in the high-breakdown-voltage transistor forming region by a Local Oxidation of Silicon (LOCOS) method and a step of forming isolation region in the low-voltage driving transistor forming region and the MONOS type memory transistor forming region by a trench isolation method.

In the method of manufacturing a semiconductor device according to one embodiment of the invention, the LOCOS method includes a recess LOCOS method and a semi-recess LOCOS method.

In the method of manufacturing a semiconductor device, the well may be formed in the low-voltage driving transistor forming region and the MONOS type memory transistor forming region before the isolation region is formed in the low-voltage driving transistor forming region and the MONOS type memory transistor forming region.

In the method of manufacturing a semiconductor device, the well may be formed in the low-voltage driving transistor forming region and the MONOS type memory transistor forming region after the isolation region is formed in the low-voltage driving transistor forming region and the MONOS type memory transistor forming region.

In the method of manufacturing a semiconductor device, the high-breakdown-voltage transistor may be formed to have an offset insulating layer.

In the method of manufacturing a semiconductor device, the offset insulating layer may be formed by a LOCOS method.

### BRIEF DESCRIPTION OF THE DRAWINGS

FIG. 1 is a sectional view showing a method for manufacturing a semiconductor device according to an embodiment of the present invention.

FIG. 2 is a sectional view showing the method for manufacturing a semiconductor device according to the embodiment of the present invention.

FIG. 3 is a sectional view showing the method for manufacturing a semiconductor device according to the embodiment of the present invention.

FIG. 4 is a sectional view showing the method for manufacturing a semiconductor device according to the embodiment of the present invention.

FIG. 5 is a sectional view showing the method for manufacturing a semiconductor device according to the embodiment of the present invention.

FIG. 6 is a sectional view showing the method for manufacturing a semiconductor device according to the embodiment of the present invention.

FIG. 7 is a sectional view showing the method for manufacturing a semiconductor device according to the embodiment of the present invention.

FIG. 8 is a sectional view showing the method for manufacturing a semiconductor device according to the embodiment of the present invention.

FIG. 9 is a sectional view showing the method for manufacturing a semiconductor device according to the embodiment of the present invention.

FIG. 10 is a sectional view showing the method for manufacturing a semiconductor device according to the embodiment of the present invention.

FIG. 11 is a sectional view showing the method for manufacturing a semiconductor device according to the embodiment of the present invention.

FIG. 12 is a sectional view showing the method for manufacturing a semiconductor device according to the embodiment of the present invention.

FIG. 13 is a sectional view showing the method for manufacturing a semiconductor device according to the embodiment of the present invention.

FIG. 14 is a sectional view showing the method for manufacturing a semiconductor device according to the embodiment of the present invention.

FIG. 15 is a sectional view showing the method for manufacturing a semiconductor device according to the embodiment of the present invention.

FIG. 16 is a sectional view showing the method for manufacturing a semiconductor device according to the embodiment of the present invention.

FIG. 17 is a sectional view showing the method for manufacturing a semiconductor device according to the embodiment of the present invention.

FIG. 18 is a sectional view showing the method for manufacturing a semiconductor device according to the embodiment of the present invention.

FIG. 19 is a sectional view showing the method for manufacturing a semiconductor device according to the embodiment of the present invention.

FIG. 20 is a sectional view showing the method for manufacturing a semiconductor device according to the embodiment of the present invention.

### DESCRIPTION OF THE PREFERRED EMBODIMENTS

Preferred embodiment of the present invention will now be described with reference to the accompanying drawings.

1. Semiconductor Device

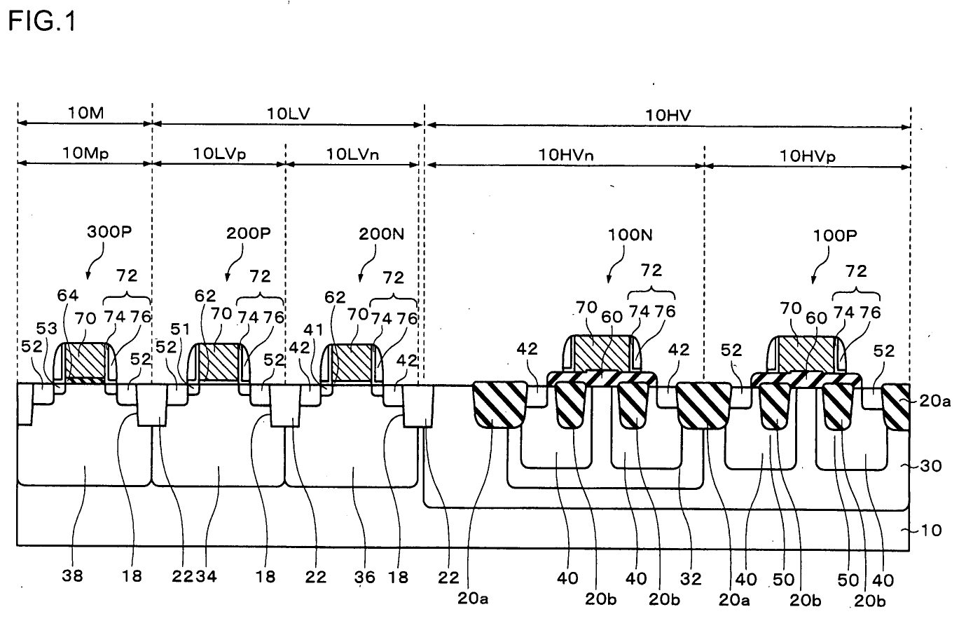

Firstly, a semiconductor device that is obtained by a manufacturing method of the present embodiment is described. FIG. 1 is a sectional view schematically showing the semiconductor device that is obtained by the manufacturing method of one embodiment of the present embodiment.

A semiconductor device includes a semiconductor layer 10. The semiconductor device has a high-breakdown-voltage transistor forming region 10HV, a low-voltage driving transistor forming region 10LV and a Metal-Oxide-Nitride-Oxide-Semiconductor (MONOS) type memory transistor forming region 10M (hereinafter called “MONOS forming region”). The high-breakdown-voltage transistor forming region 10HV includes an n-type high-breakdown-voltage transistor forming region 10HVn and a p-type high-breakdown-voltage transistor forming region 10HVp. The low-voltage driving transistor forming region 10LV includes an n-type low-voltage driving transistor forming region 10LVn and a p-type low-voltage driving transistor forming region 10LVp. The MONOS forming region 10M includes a p-type MONOS type memory transistor forming region 10Mp (hereinafter called “p-type MONOS forming region”).

An n-type high-breakdown-voltage transistor 100N is formed in the n-type high-breakdown-voltage transistor forming region 10HVn, and a p-type high-breakdown-voltage transistor 100P is formed in the p-type high-breakdown-voltage transistor forming region 10HVp. In the same way, an n-type low-voltage driving transistor 200N is formed in the n-type low-voltage driving transistor forming region 10LVn, and a p-type low-voltage driving transistor 200P is formed in the p-type low-voltage driving transistor forming region 10LVp. In the p-type MONOS forming region 10Mp, a p-type MONOS type memory transistor 300P is formed.

In other words, the n-type high-breakdown-voltage transistor 100N, the p-type high-breakdown-voltage transistor 100P, the n-type low-voltage driving transistor 200N, the p-type low-voltage driving transistor 200P and the p-type MONOS type memory transistor 300P are all provided on the same substrate (the same chip). Though only five transistors are depicted in FIG. 1, this is for the sake of simplicity and it will be obvious that each transistor is provided in a plural number on the same substrate. For example, an n-type MONOS type memory transistor could be formed in the MONOS forming region 10M.

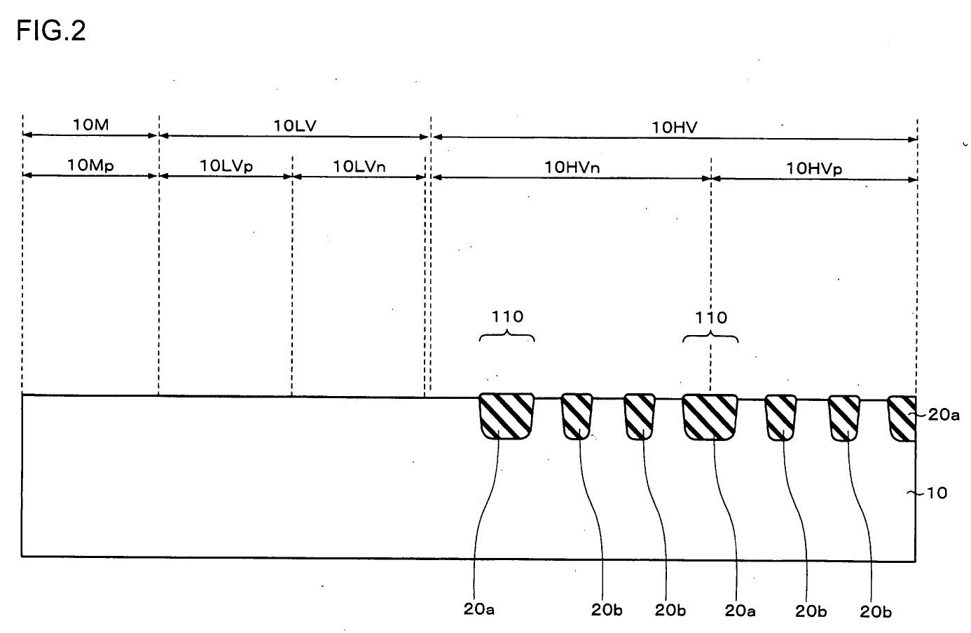

In the high-breakdown-voltage transistor forming region 10HV, the n-type high-breakdown-voltage transistor 100N and the p-type high-breakdown-voltage transistor 100P are formed. A first isolation region 110 (see FIG. 2) is provided between the n-type high-breakdown-voltage transistor 100N and the p-type high-breakdown-voltage transistor 100P that are adjacent each other. The first isolation region 110 is made of a semi-recess Local Oxidation of Silicon (LOCOS) layer.

Next, structure of the n-type high-breakdown-voltage transistor 100N and the p-type high-breakdown-voltage transistor 100P is explained.

The n-type high-breakdown-voltage transistor 100N includes a first gate insulating layer 60, an offset insulating layer 20b that is made of the semi-recess LOCOS layer, a gate electrode 70, an n-type offset region 40, a side-wall insulating layer 72 and an n-type source/drain region 42.

The first gate insulating layer 60 is formed at least over a channel region within a p-type first well 32. The p-type first well 32 is formed within an n-type first well 30. The offset insulating layer 20b is provided at the both sides of the first gate insulating layer 60 and within the n-type offset region 40. The gate electrode 70 is formed at least on the first gate insulating layer 60. The n-type offset region 40 is formed within the p-type first well 32. The side-wall insulating layer 72 is formed on a side surface of the gate electrode 70. The side-wall insulating layer 72 includes, for example, an oxide silicon layer 74 whose shape of cross section is L-shaped and a nitride silicon layer 76 formed on the oxide silicon layer 74. The n-type source/drain region 42 is provided outside the side-wall insulating layer 72 and within the semiconductor layer 10.

The p-type high-breakdown-voltage transistor 100P includes the first gate insulating layer 60, the offset insulating layer 20b that is made of the semi-recess LOCOS layer, the gate electrode 70, a p-type offset region 50, the side-wall insulating layer 72 and a p-type source/drain region 52.

The first gate insulating layer 60 is formed at least over a channel region within the n-type first well 30. The offset insulating layer 20b is provided at the both sides of the first gate insulating layer 60 and within the p-type offset region 50. The gate electrode 70 is formed at least on the first gate insulating layer 60. The p-type offset region 50 is formed within the n-type first well 30. The side-wall insulating layer 72 is formed on the side surface of the gate electrode 70. The side-wall insulating layer 72 includes, for example, the oxide silicon layer 74 whose shape of cross section is L-shaped and the nitride silicon layer 76 formed on the oxide silicon layer 74. The p-type source/drain region 52 is provided outside the side-wall insulating layer 72 and within the semiconductor layer 10.

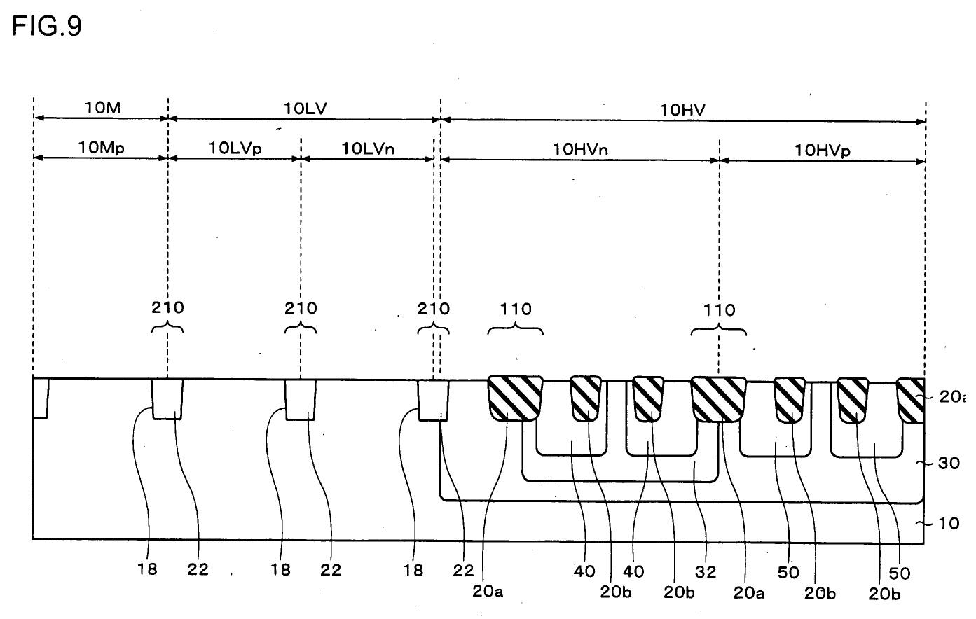

Next, the low-voltage driving transistor forming region 10LV is described. In the low-voltage driving transistor forming region 10LV, the n-type low-voltage driving transistor 200N and the p-type low-voltage driving transistor 200P are formed. A second isolation region 210 (see FIG. 9) is provided between the n-type low-voltage driving transistor 200N and the p-type low-voltage driving transistor 200P that are adjacent each other.

Next, structure of each transistor is described.

The n-type low-voltage driving transistor 200N includes a second gate insulating layer 62, the gate electrode 70, the side-wall insulating layer 72, an n-type extension region 41 and the n-type source/drain region 42.

The second gate insulating layer 62 is formed at least over a channel region within a p-type second well 36. The gate electrode 70 is formed on the second gate insulating layer 62. The side-wall insulating layer 72 is formed on the side surface of the gate electrode 70. The side-wall insulating layer 72 includes, for example, the oxide silicon layer 74 whose shape of cross section is L-shaped and the nitride silicon layer 76 formed on the oxide silicon layer 74. The n-type extension region 41 is formed within the p-type second well 36. The n-type source/drain region 42 is provided outside the side-wall insulating layer 72 and within the semiconductor layer 10.

The p-type low-voltage driving transistor 200P includes the second gate insulating layer 62, the gate electrode 70, the side-wall insulating layer 72, a p-type extension region 51 and the p-type source/drain region 52.

The second gate insulating layer 62 is formed at least over a channel region within an n-type second well 34. The gate electrode 70 is formed on the second gate insulating layer 62. The side-wall insulating layer 72 is formed on the side surface of the gate electrode 70. The side-wall insulating layer 72 includes, for example, the oxide silicon layer 74 whose shape of cross section is L-shaped and the nitride silicon layer 76 formed on the oxide silicon layer 74. The p-type extension region 51 is formed within the n-type second well 34. The p-type source/drain region 52 is provided outside the side-wall insulating layer 72 and within the semiconductor layer 10.

Next, the MONOS forming region 10M is described. In the MONOS forming region 10M, the p-type MONOS type memory transistor 300P is provided. The p-type MONOS type memory transistor 300P includes a third gate insulating layer 64, the gate electrode 70, the side-wall insulating layer 72, the p-type extension region 51 and the p-type source/drain region 52.

The third gate insulating layer 64 is a film stack in which a first oxide silicon layer, a nitride silicon layer and a second oxide silicon layer are stacked in layers. A high electric field is produced in the first oxide silicon layer by a voltage applied to the third gate insulating layer 64, and a threshold voltage is modulated to perform a writing operation or an erasing operation by moving an electron back and forth between a semiconductor layer and an interface between the first oxide silicon layer and the nitride silicon layer directly with the tunnel effect. The interface between the first oxide silicon layer and the nitride silicon layer has an electron trap level, and information is recorded and held by trapping an electron there.

The third gate insulating layer 64 is formed at least over a channel region within an n-type third well 38. The gate electrode 70 is formed on the third gate insulating layer 64. The side-wall insulating layer 72 is formed on the side surface of the gate electrode 70. The side-wall insulating layer 72 includes, for example, the oxide silicon layer 74 whose shape of cross section is L-shaped and the nitride silicon layer 76 formed on the oxide silicon layer 74. The p-type source/drain region 52 is provided outside the side-wall insulating layer 72 and within the semiconductor layer 10.

Next, a method of manufacturing a semiconductor device of the present embodiment will be described with reference to FIGS. 1 through 18. FIGS. 1 through 18 are sectional views schematically showing steps of the method for manufacturing a semiconductor device of the present embodiment.

(1) First, as shown in FIG. 2, a semi-recess LOCOS layer 20a that serves as isolation and the offset insulating layer 20b for an electric field relaxation are formed in the high-breakdown-voltage transistor forming region 10HV. An example of a method of forming the semi-recess LOCOS layer 20a and the offset insulating layer 20b is given below.

Next, an oxide nitride silicon layer is formed on the semiconductor layer 10 by chemical vapor deposition (CVD). The semiconductor layer 10 at least includes silicon and is made of silicon, silicon-germanium and the like. The semiconductor layer 10 may be a silicon layer in a bulk silicon substrate or a silicon on insulator (SIO) substrate. A thickness of the oxide nitride silicon layer is, for example, 8-12 nm. Then, a nitride silicon layer is formed on the oxide nitride silicon layer by CVD. And then, a resist layer that has an opening corresponding to where the semi-recess LOCOS layer 20a and the offset insulating layer 20b are formed is formed on the nitride silicon layer. Subsequently, a concave part is formed in a forming region of the semi-recess LOCOS layer 20a and the offset insulating layer 20b by etching the nitride silicon layer, the oxide nitride silicon layer and the semiconductor layer 10 using the resist layer as mask. Then, the resist layer is removed.

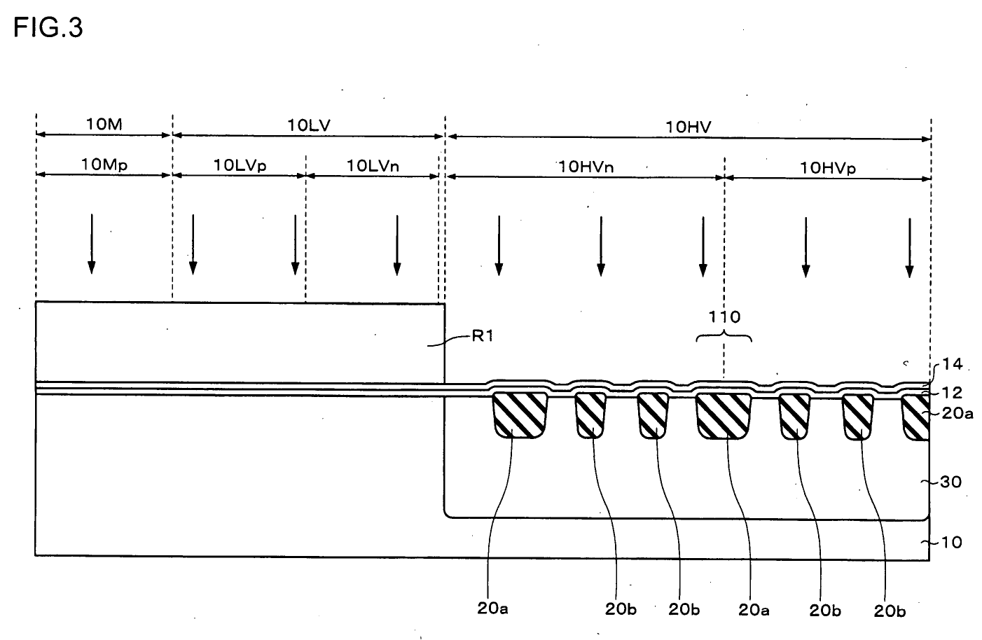

After that, as shown in FIG. 3, an oxide silicon layer is formed on the exposed surface of the semiconductor layer 10 by thermal oxidation, and then the semi-recess LOCOS layer 20a that serves as the first isolation region 110 defining the high-breakdown-voltage transistor forming region 10HV is formed. And the offset insulating layer 20b of the high-breakdown-voltage transistor 100P and 100N is also formed.

(2) Secondly, as shown in FIG. 3, the n-type first well 30 is formed in the high-breakdown-voltage transistor forming region 10HV. First, a sacrificial oxide layer 12 is formed on the whole surface of the semiconductor layer 10. As the sacrificial oxide layer 12, for example, an oxide silicon film is formed. Then, a stopper layer 14 is formed on the sacrificial oxide layer 12. As the stopper layer 14, for example, nitride silicon can be used. The stopper layer 14 is formed, for example, by CVD.

Then, a resist layer R1 having a prescribed pattern is formed. After an n-type impurity such as phosphorus and arsenic is injected into the semiconductor layer 10 once or more than once using the resist layer R1 as a mask, the resist layer R1 is removed by, for example, ashing. And then, the impurity layer is diffused with a heat treatment and the n-type first well 30 is formed in the semiconductor layer 10.

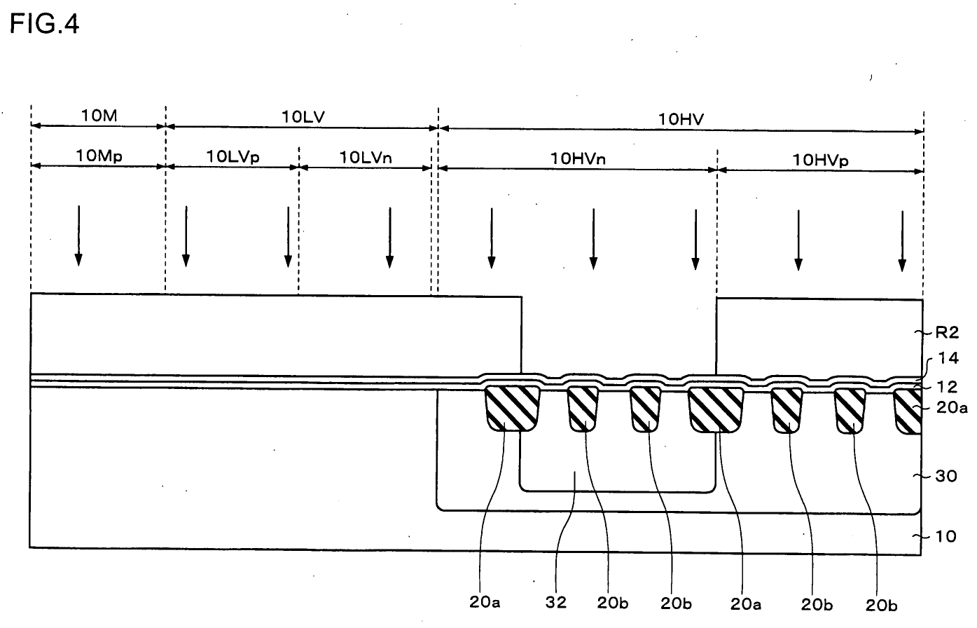

(3) Next, as shown in FIG. 4, the p-type first well 32 is formed in the high-breakdown-voltage transistor forming region 10HV. First, a resist layer R2 having a prescribed pattern is formed. After a p-type impurity is injected into the semiconductor layer 10 once or more than once using the resist layer R2 as a mask, the resist layer R2 is removed by, for example, ashing. And then, the impurity layer is diffused with the heat treatment and the p-type first well 32 is formed.

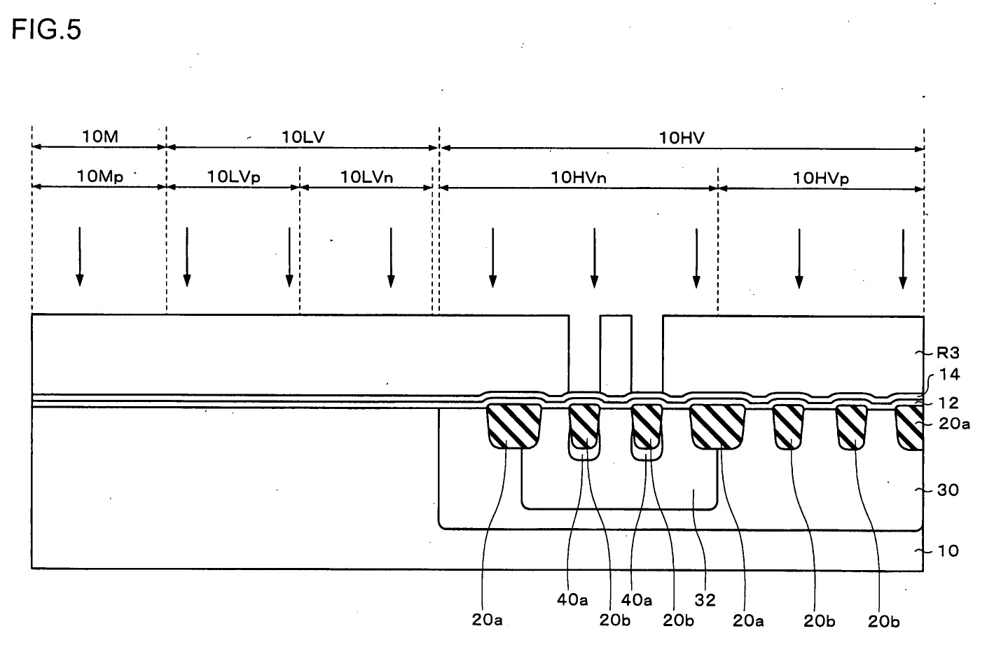

(4) Next, as shown in FIG. 5, an impurity layer 40a for the offset region is formed in the n-type high-breakdown-voltage transistor forming region 10HVn. First, a resist layer R3 covering a certain pattern is formed. The impurity layer 40a is formed by introducing an n-type impurity into the semiconductor layer 10 using the resist layer R3 as a mask. After that, the resist layer R3 is removed.

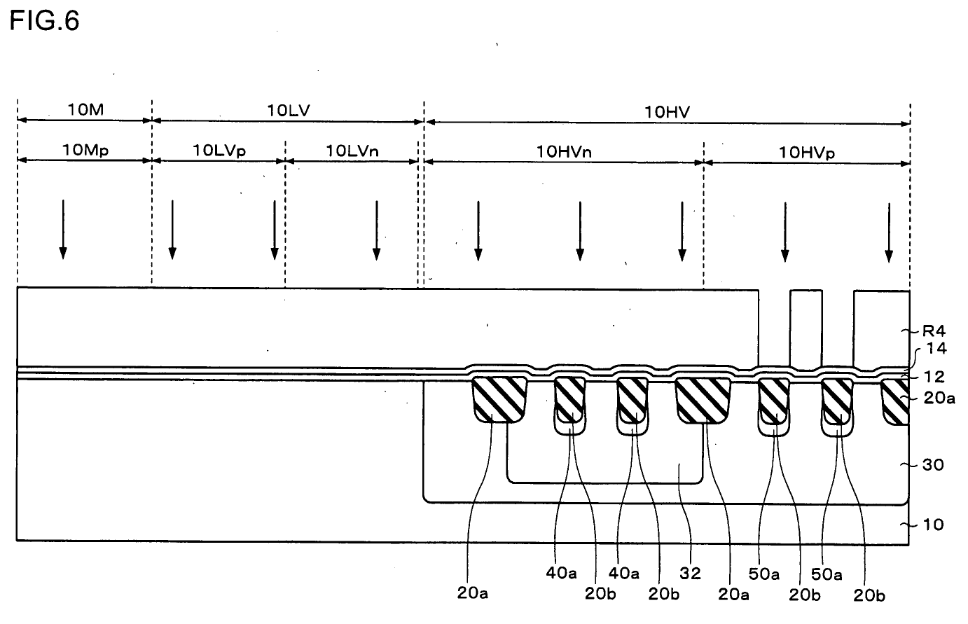

(5) Subsequently, as shown in FIG. 6, an impurity layer 50a for the offset region is formed in the p-type high-breakdown-voltage transistor forming region 10HVp. First, a resist layer R4 covering a certain area is formed. The impurity layer 50a is formed by introducing a p-type impurity into the semiconductor layer 10 using the resist layer R4 as a mask. After that, the resist layer R4 is removed. The step (4) and the step (5) can be performed in reverse order from that of this embodiment.

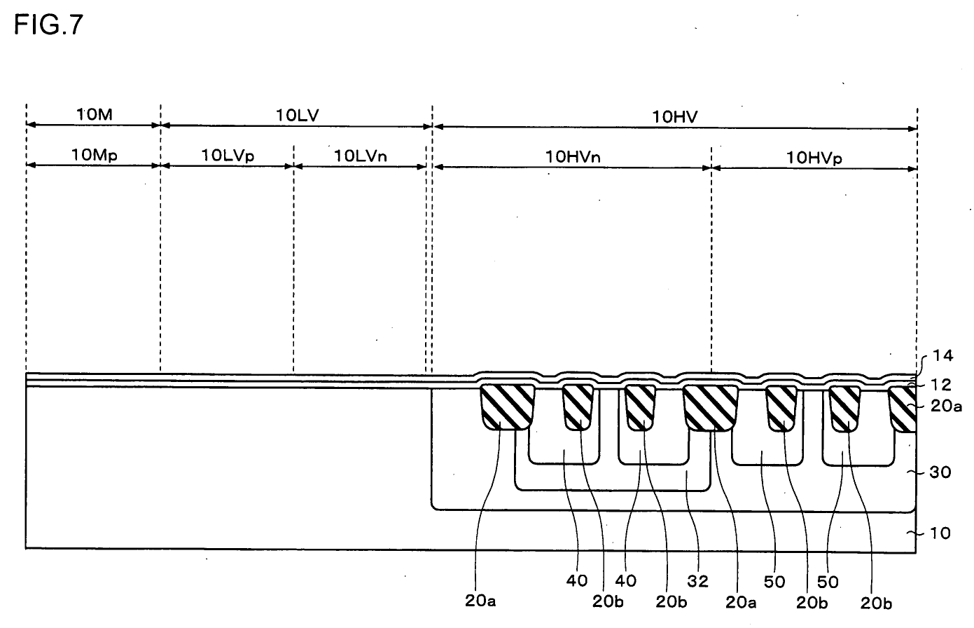

(6) Then, as shown in FIG. 7, the impurity layers 40a and 50a are diffused by a heat treatment of conventional technique and the offset regions 40 and 50 of the respective high-breakdown-voltage transistor 100P and 100N are formed.

(7) Next, the second isolation region 210 is formed by forming a trench insulating layer 22 in the low-voltage driving transistor forming region 10LV and the MONOS forming region 10M (see FIG. 9).

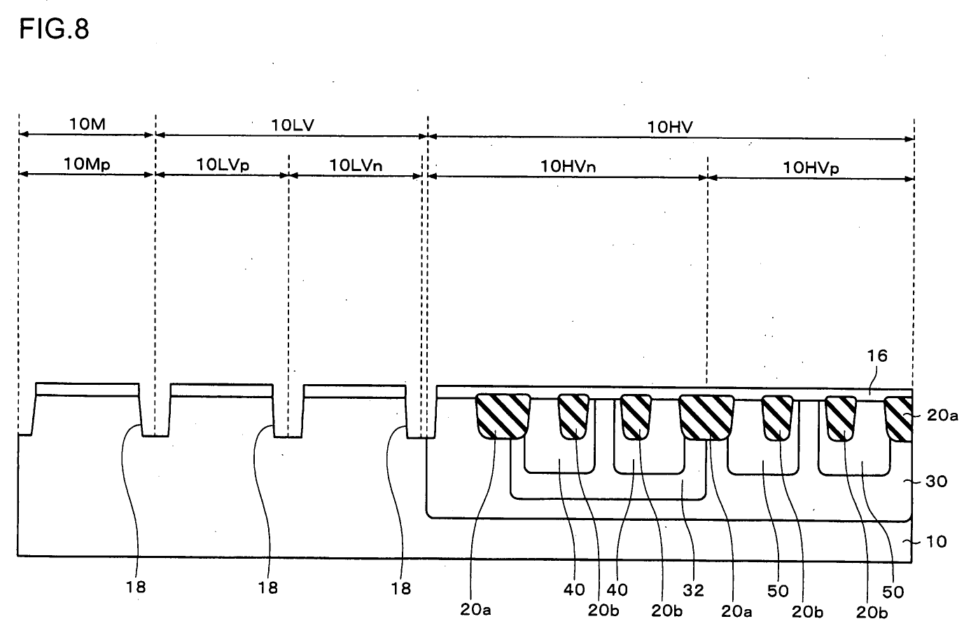

First, as shown in FIG. 8, a stopper layer 16 is formed on the whole surface of the semiconductor layer 10. As the stopper layer 16, for example, a film stack of an oxide nitride silicon layer and a nitride film formed the oxide nitride silicon layer can be used. The stopper layer 16 is formed, for example, by CVD. Then, a mask layer (not shown in the figures) that has an opening corresponding to where the second isolation region 210 (see FIG. 9) is going to be formed is formed on the stopper layer 16. As shown in FIG. 8, the stopper layer 16 and the semiconductor layer 10 are etched using as the mask layer as a mask by conventional etching technique. Consequently, a trench 18 is formed.

(8) Next, a trench oxide film (not shown in FIG. 9) is formed on the trench 18. The trench oxide film is formed by, for example, thermal oxidation. A thickness of the trench oxide film is, for example, 50-500 nm.

Subsequently, an insulating layer (not shown in FIG. 9) is deposited on the whole surface so as to fill in the trench 18. After the deposited insulating layer is polished until the stopper layer 16 is exposed by, for example, chemical mechanical polishing (CMP), the stopper layer 16 is removed by etching until the surface of the semiconductor layer 10 is exposed. Consequently, the trench insulating layer 22 is obtained.

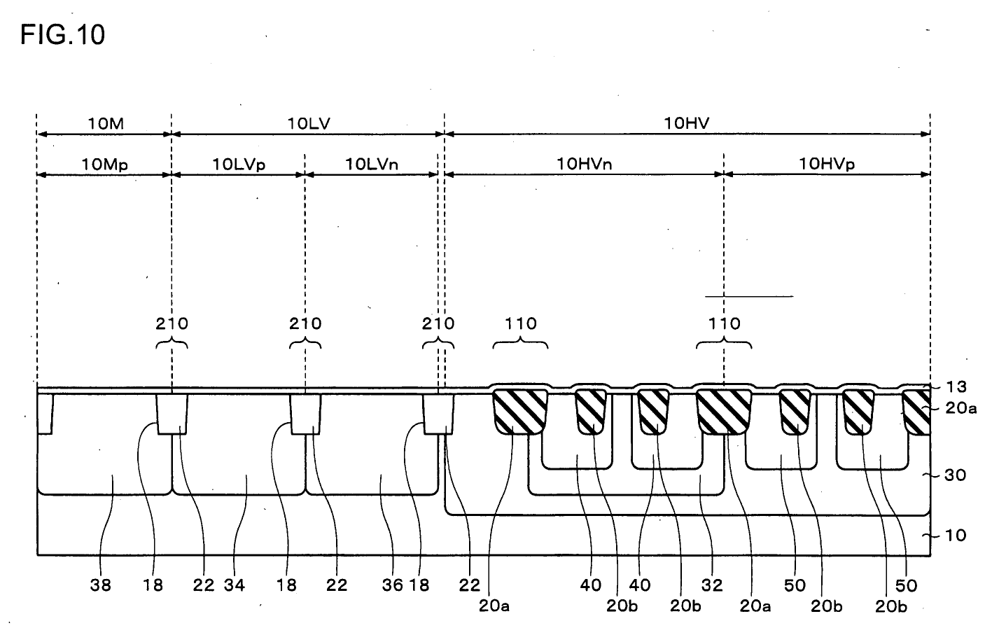

(9) Then, as shown FIG. 10, a sacrificial oxide layer 13 is formed on the whole surface of the semiconductor layer 10. As the sacrificial oxide layer 13, for example, oxide silicon can be used. The sacrificial oxide layer 13 can be formed by, for example, thermal oxidation.

Then, a well is formed in the low-voltage driving transistor forming region 10LV and the MONOS forming region 10M. First, a resist layer is formed so as to cover the whole surface other than the p-type low-voltage driving transistor forming region 10LVp and the p-type MONOS forming region 10Mp. Then, the n-type second well 34 is formed in the p-type low-voltage driving transistor forming region 10LVp and the n-type third well 38 is formed on the p-type MONOS forming region 10Mp by injecting an n-type impurity such as phosphorus and arsenic once or more than once using the resist layer as a mask. An injection volume of the n-type impurity will be decided in consideration of a thermal diffusion volume of the n-type impurity in a step (13). In the step (13), the first gate insulating layer 60 of the high-breakdown-voltage transistor is formed. Details of the step (13) will be described later. Then, the resist layer is removed.

Subsequently, a resist layer is formed so as to cover the whole surface other than the n-type low-voltage driving transistor forming region 10LVn. Then, the p-type second well 36 is formed by injecting a p-type impurity such as boron once or more than once using the resist layer as a mask. An injection volume of the p-type impurity will be decided in consideration of a thermal diffusion volume of the p-type impurity in the later-described step (13). In the step (13), the first gate insulating layer 60 of the high-breakdown-voltage transistor is formed. Then, the resist layer is removed. After this, if necessary, channel-doping in the low-voltage driving transistor forming region 10LV and the MONOS forming region 10M may be performed.

Since the well is formed in the low-voltage driving transistor forming region 10LV and the MONOS forming region 10M before a step (11) in which a stack film 64a is formed, an impurity injection through the stack film 64a is not needed. Therefore, injection damage to the stack film 64a will be avoided and the impurity injection can be accurately performed. Details of the step (11) will be described later.

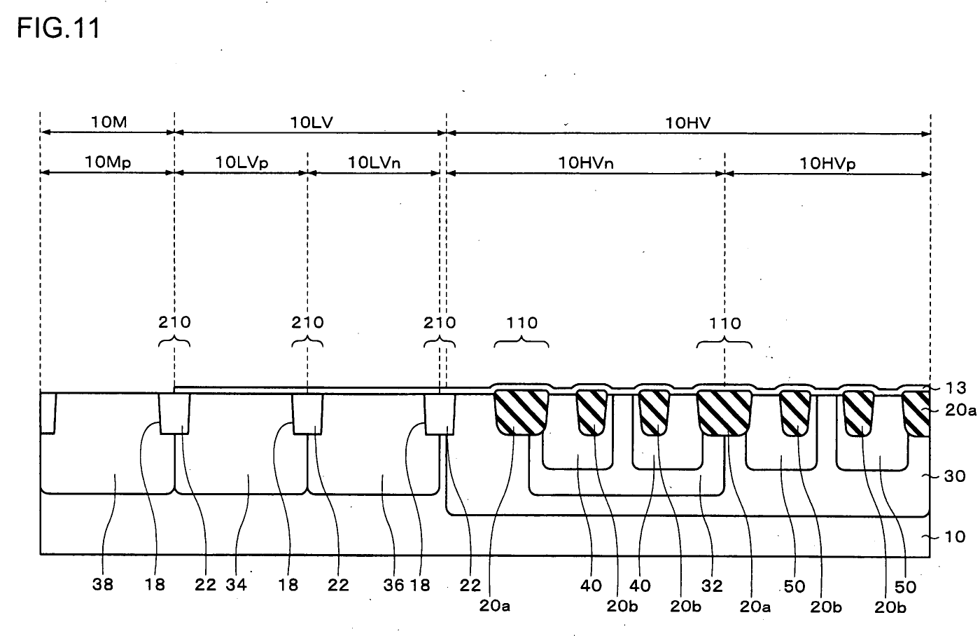

(10) Next, as shown in FIG. 11, the sacrificial oxide layer 13 in the MONOS forming region 10M is removed. The sacrificial oxide layer 13 can be removed by, for example, wet-etching using hydrofluoric acid.

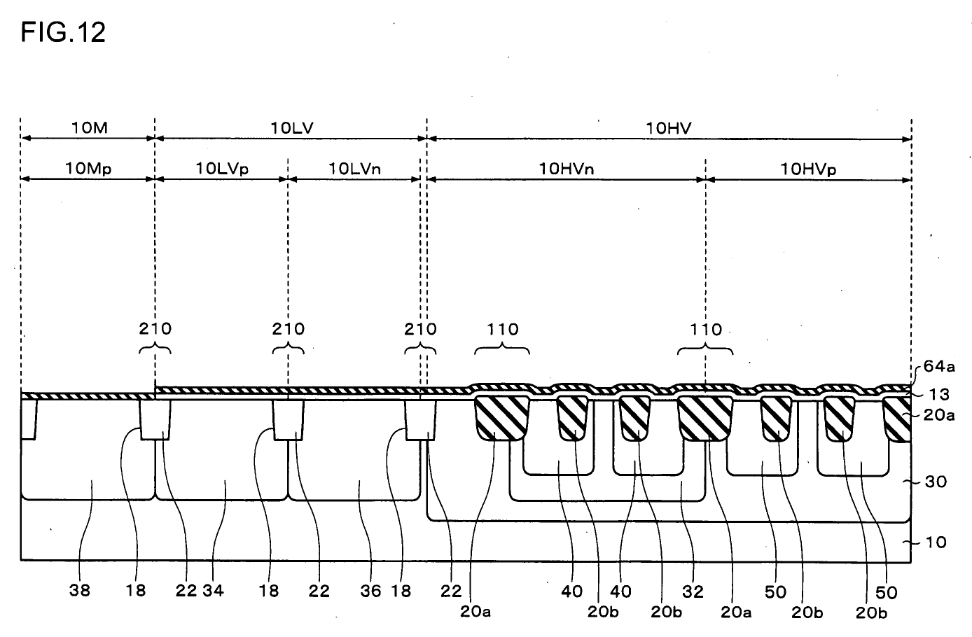

(11) Then, as shown in FIG. 12, the stack film 64a that consists of the first oxide silicon layer, the nitride silicon layer and the second oxide silicon layer is formed on the whole surface of the wafer. The first oxide silicon layer can be formed by, for example, thermal oxidation. The nitride silicon layer and the second oxide silicon layer can be formed, for example, by CVD.

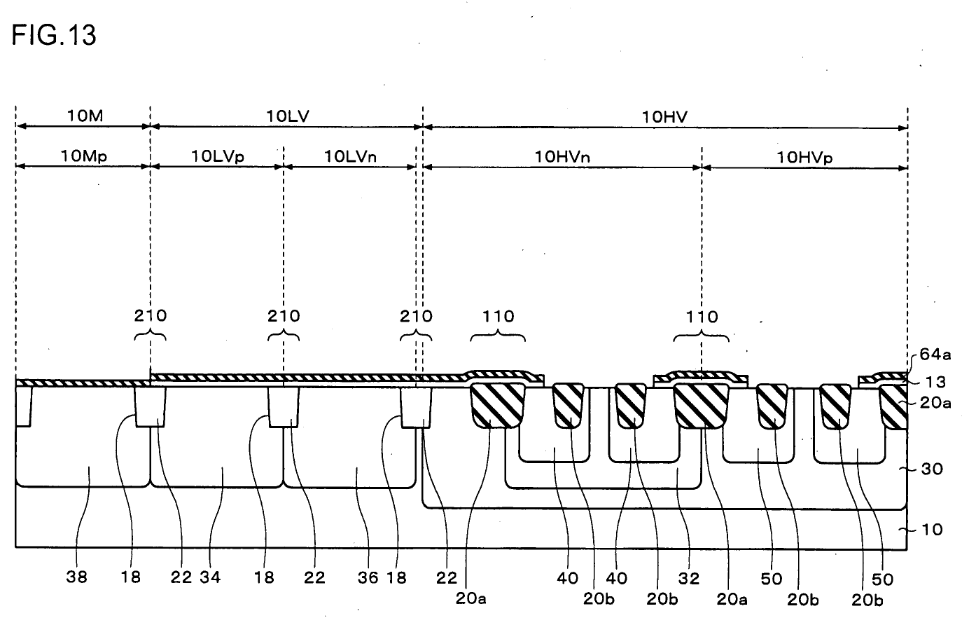

(12) Subsequently, a resist layer (not shown in the figures) is formed in the high-breakdown-voltage transistor forming region 10HV so as to cover the whole surface other than the first gate insulating layer 60 of the n-type high-breakdown-voltage transistor 100N and the first gate insulating layer 60 of the p-type high-breakdown-voltage transistor 100P (see FIG. 1). As shown in FIG. 13, the exposed stack film 64a and the sacrificial oxide layer 13 are removed. After this, if necessary, channel-doping in the high-breakdown-voltage transistor forming region 10HV may be performed.

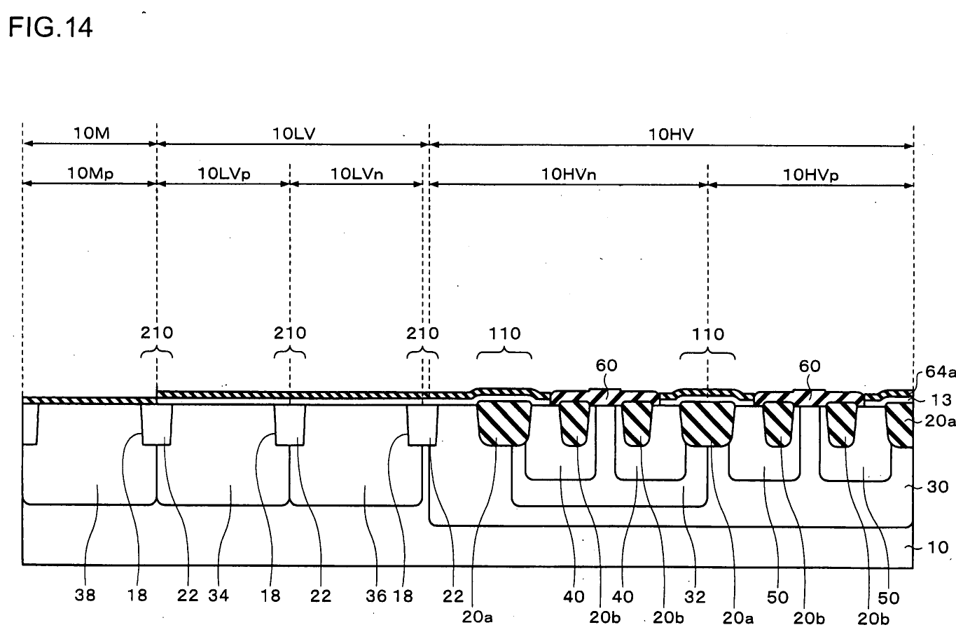

(13) Next, as shown in FIG. 14, the first gate insulating layer 60 is formed in the high-breakdown-voltage transistor forming region 10HV. The first gate insulating layer 60 can be formed by selective thermal oxidation using the stack film 64a as an anti-oxidation film. A thickness of the first gate insulating layer 60 is, for example, 50-200 nm.

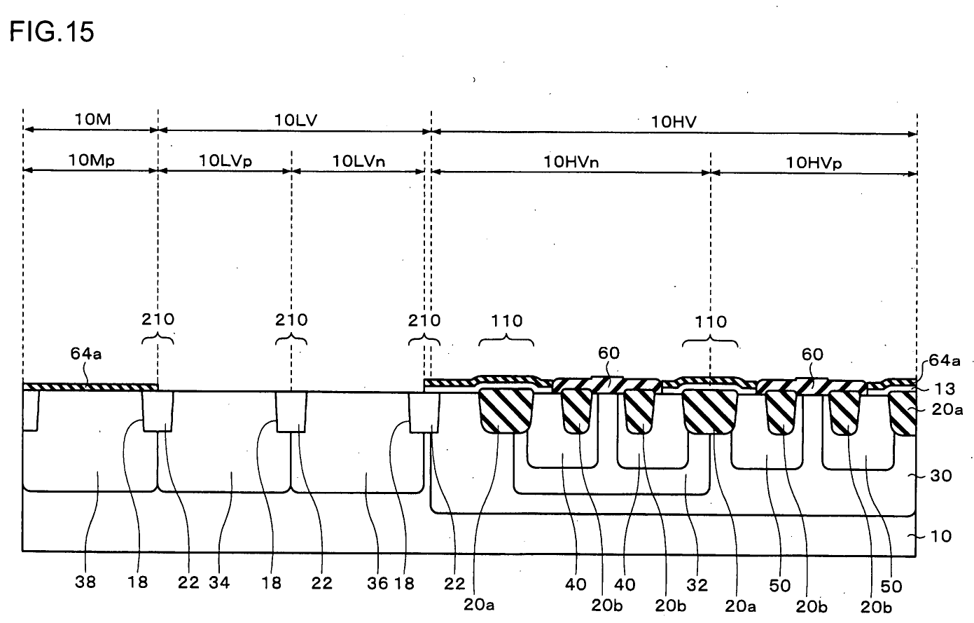

(14) Then, a resist layer (not shown in the FIG. 15) is formed so as to cover the high-breakdown-voltage transistor forming region 10HV and the MONOS forming region 10M, and the exposed stack film 64a and the sacrificial oxide layer 13 are removed. The stack film 64a can be removed by, for example, wet-etching, dry-etching, or a combination of the wet-etching and the dry-etching. And then, the resist layer is removed by ashing.

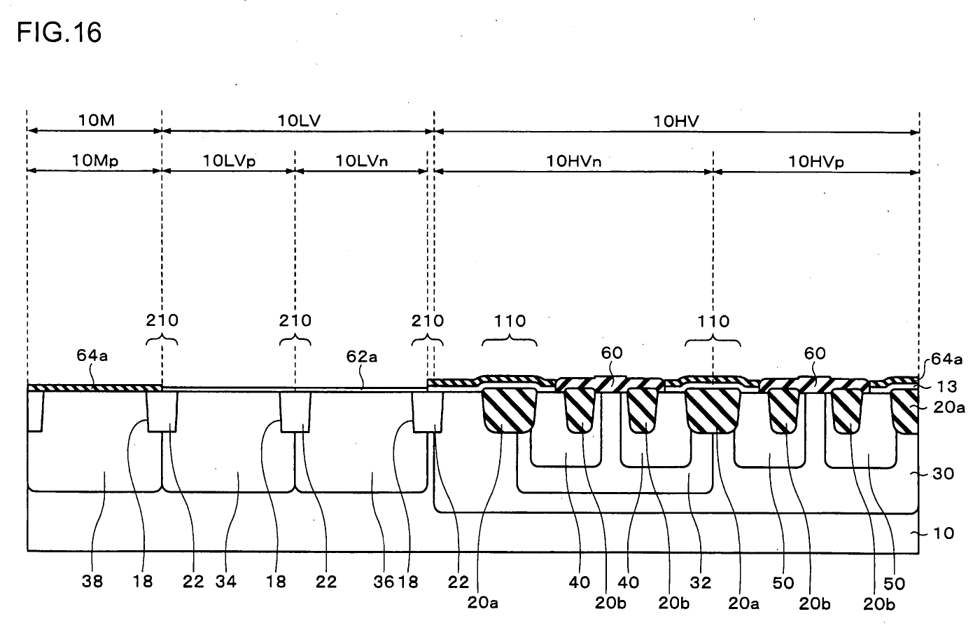

(15) Subsequently, as shown in FIG. 16, an insulating layer 62a is formed. The insulating layer 62a will become the gate insulating layer 62 of the n-type low-voltage driving transistor 200N and the gate insulating layer 62 of the p-type low-voltage driving transistor 200P (see FIG. 1). The insulating layer 62a can be formed by, for example, thermal oxidation. A thickness of the insulating layer 62a is, for example, 1.6-15 nm.

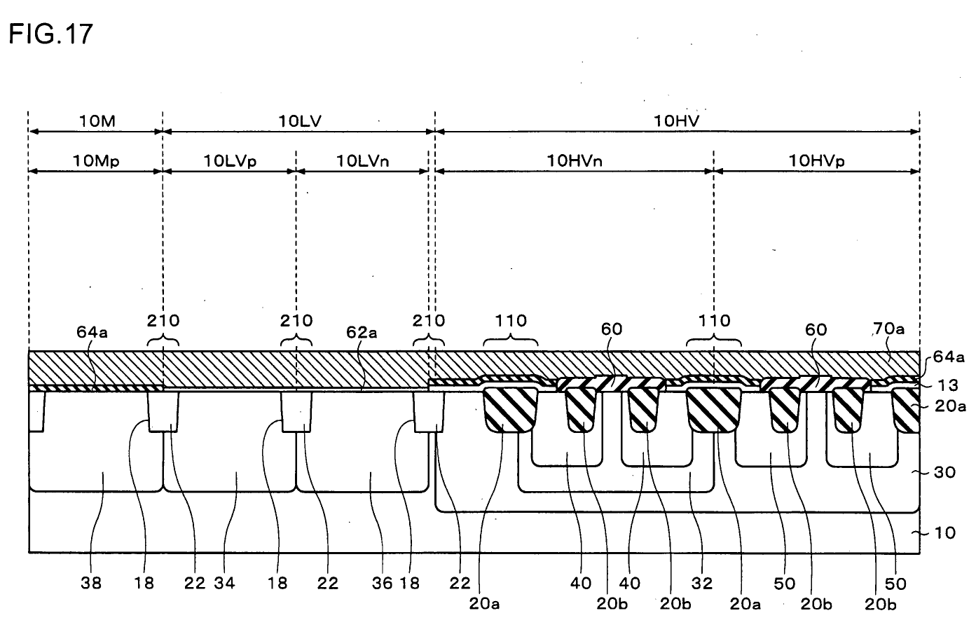

(16) Then, as shown in FIG. 17, a conductive layer 70a is formed on the whole surface of the high-breakdown-voltage transistor forming region 10HV, the low-voltage driving transistor forming region 10LV and the MONOS forming region 10M. As the conductive layer 70a, for example, a polysilicon layer can be used. When the conductive layer 70a is made of polysilicon, resistance of the conductive layer 70a can be decreased by injecting impurities into the conductive layer 70a with ion implantation.

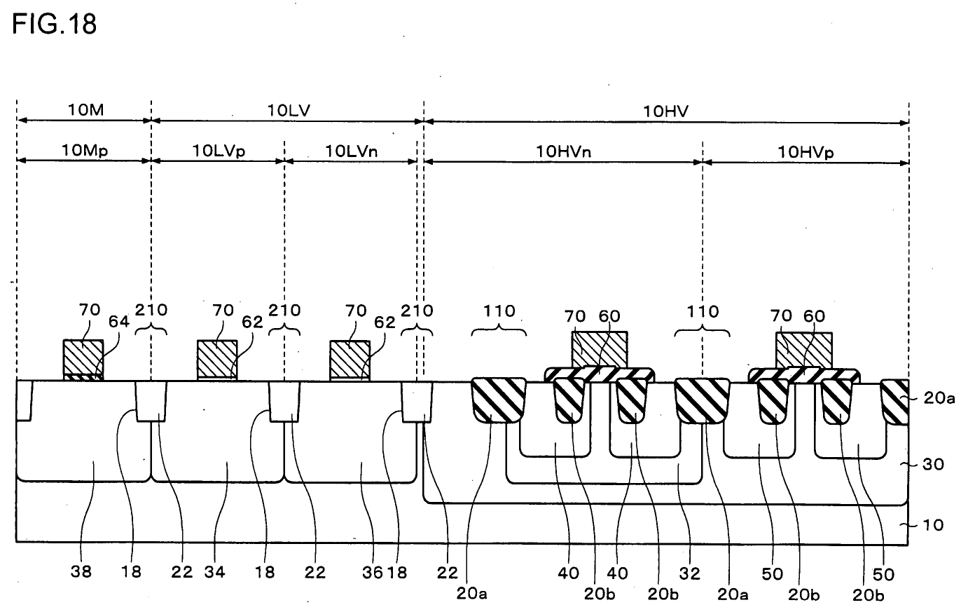

(17) Next, as shown in FIG. 18, the gate electrode 70 of each transistor is formed. Furthermore, the gate insulating layer 62 of the n-type low-voltage driving transistor 200N, the gate insulating layer 62 of the p-type low-voltage driving transistor 200P and the gate insulating layer 64 of the p-type MONOS type memory transistor 300P are formed. More specifically, firstly, a resist layer (not shown in the figures) that has a prescribed pattern is formed. Secondly, the conductive layer 70a, the insulating layer 62a and the stack film 64a (see FIG. 17) are patterned as using the resist layer as a mask. As a result, the gate electrode 70 of each transistor, the gate insulating layer 62 of the n-type low-voltage driving transistor 200N, the gate insulating layer 62 of the p-type low-voltage driving transistor 200P and the gate insulating layer 64 of the p-type MONOS type memory transistor 300P are obtained.

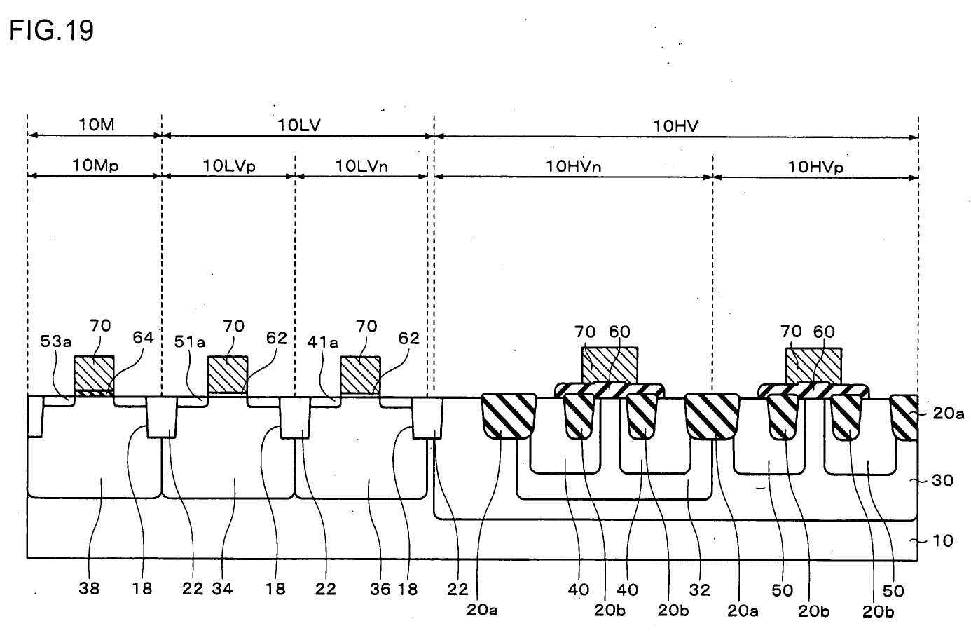

(18) Then, as shown in FIG. 19, an impurity layer 41a that is going to be the n-type extension region is formed in the n-type low-voltage driving transistor forming region 10LVn. An impurity layer 51a that is going to be the p-type extension region is formed in the p-type low-voltage driving transistor forming region 10LVp. An impurity layer 53a that is going to be the p-type extension region is formed in the p-type MONOS forming region 10Mp. The impurity layers 41a, 51a and 53a can be formed in such a way that a mask is formed by prevailing photolithography and a predetermined impurity is injected.

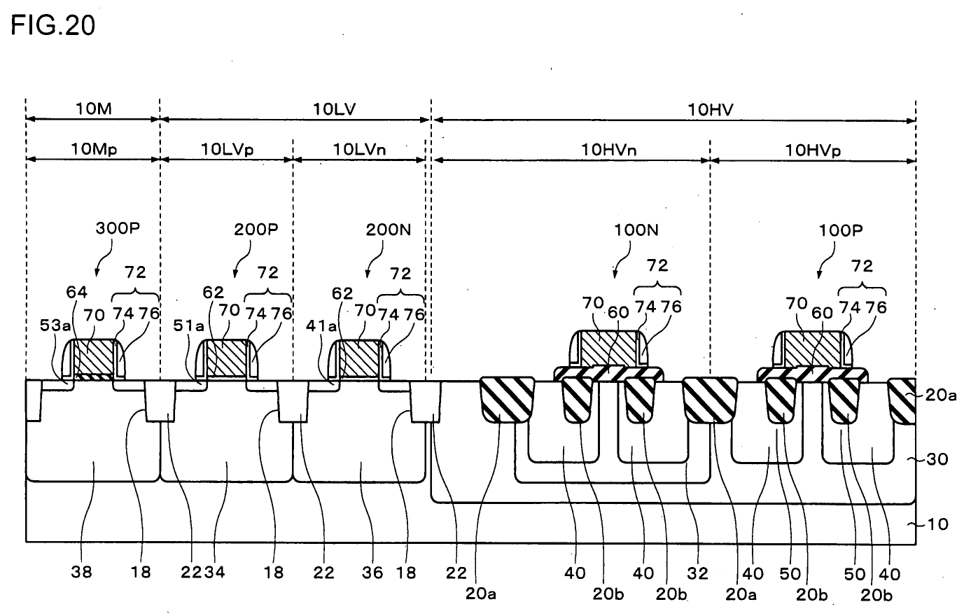

(19) Next, as shown in FIG. 20, an insulting layer (not shown in the figures) is formed on the whole surface. The side-wall insulating layer 72 is formed on the side surface of the gate electrode 70 by anisotropically etching the insulating layer. In the example shown in the figure, the insulating layer is, for example, a laminated film that consists of the oxide silicon layer 74 and the nitride silicon layer 76 formed on the oxide silicon layer 74. In such case, as shown in FIG. 20, the oxide silicon layer 74 is formed on an upper surface of the semiconductor layer 10 and sides of each gate electrode 70 so as to have an L-shaped section. A thickness of the oxide silicon layer 74 is, for example, about 10 nm. A thickness of the nitride silicon layer 76 is, for example, about 70 nm.

(20) Then, as shown in FIG. 1, the n-type source/drain region 42 is formed within the semiconductor layer 10 and outside the side-wall insulating layer 72 by injecting an n-type impurity into a certain area of the semiconductor layer 10 in the n-type high-breakdown-voltage transistor forming region 10HVn and the n-type low-voltage driving transistor forming region 10LVn. The n-type source/drain region 42 can be formed by a commonly-used way.

Next, the p-type source/drain region 52 is formed within the semiconductor layer 10 and outside the side-wall insulating layer 72 by injecting a p-type impurity into a certain area of the semiconductor layer 10 in the p-type high-breakdown-voltage transistor forming region 10HVp, the p-type low-voltage driving transistor forming region 10LVp and the p-type MONOS forming region 10Mp. The n-type source/drain region 42 can be formed by commonly-used way. The p-type source/drain region 52 can be formed by a commonly-used way.

The semiconductor device according to the present embodiment is manufactured through the above-mentioned steps. According to the method of forming a semiconductor device of the present invention, there are following features.

According to the method of manufacturing a semiconductor device of the present embodiment, the high-breakdown-voltage transistor, which requires a high temperature process compared with the low-voltage driving transistor in order to form a deep well and a thick gate insulating electrode, and the MONOS type memory transistor that requires a special stack film forming process can be provided together in the same substrate.

According to the method of forming a semiconductor device of the present embodiment, in the step (13), in which the first gate insulating layer 60 of the n-type high-breakdown-voltage transistor 100N and the p-type high-breakdown-voltage transistor 100P is formed by selective thermal oxidation, an area other than where the first gate insulating layer 60 is formed is covered with the stack film 64a. In other words, the stack film 64a serves as the anti-oxidation film. Therefore, the manufacturing steps can be simplified by using the stack film 64a, which is the insulating layer of the MONOS type memory transistor, as the anti-oxidation film, compared with a case in which a nitride silicon film is separately formed as the anti-oxidation film through another step.

The present invention is not limited to the embodiments described above but applied to various kinds of modifications within the scope and spirit of the present invention. For example, though the MONOS type memory transistor is explained in the above-described embodiment, a MNOS type memory transistor can be formed by the same manufacturing method. Stated another way, the stack film 64a may consist of at least two layers, which are the oxide silicon film and the nitride film.

Also, for example, in the above-described embodiment, the semi-recess LOCOS method is employed to form the offset insulating layer 20b. However, the offset insulating layer 20b can be formed by a LOCOS method or a recess LOCOS method.

Furthermore, for example, in the above-described embodiment, the well in the low-voltage driving transistor forming region 10LV and the MONOS forming region 10M is formed after the trench insulating layer 22 is formed. However, the well in the low-voltage driving transistor forming region 10LV and the MONOS forming region 10M may be formed before the trench insulating layer 22 is formed, in other words before the above-mentioned step (7).

Furthermore, for example, in the above-described embodiment, the well in the low-voltage driving transistor forming region 10LV and the MONOS forming region 10M is formed before the first gate insulating layer 60 in the high-breakdown-voltage transistor. However, the well in the low-voltage driving transistor forming region 10LV and the MONOS forming region 10M may be formed after the first gate insulating layer 60 is formed, in other words after the above-mentioned step (13). In such case, it is not necessary to perform impurity injection in advance in consideration of a thermal diffusion volume of the impurity. As a result, the depth of the well can be accurately controlled

1. A method of manufacturing a semiconductor device having a high-breakdown-voltage transistor, a low-voltage driving transistor and a Metal-Nitride-Oxide-Semiconductor (MNOS) type memory transistor, comprising:
forming a stack film that includes at least an oxide silicon layer and a nitride silicon layer over a high-breakdown-voltage transistor forming region where the high-breakdown-voltage transistor is formed, a low-voltage driving transistor forming region where the low-voltage driving transistor is formed and a MNOS type memory transistor forming region where the MNOS type memory transistor is formed in a semiconductor layer;
removing the stack film formed in a first gate insulating layer forming region of the high-breakdown-voltage transistor;
forming a first gate insulating layer in the high-breakdown-voltage transistor forming region by thermal oxidation;
removing the stack film formed in the low-voltage driving transistor forming region;
forming a second gate insulating layer in the low-voltage driving transistor forming region;
forming gate electrodes in the high-breakdown-voltage transistor forming region, the low-voltage driving transistor forming region and the MNOS type memory transistor forming region; and
forming source/drain regions in the high-breakdown-voltage transistor forming region, the low-voltage driving transistor forming region and the MNOS type memory transistor forming region.

2. The method of manufacturing a semiconductor device according to claim 1, wherein the stack film is formed such that a first oxide silicon layer, a nitride silicon layer and a second oxide silicon layer are stacked in layers.

3. The method of manufacturing a semiconductor device according to claim 1 or claim 2, further comprising:
forming a sacrificial oxide layer over the semiconductor layer before the stack film is formed.

4. The method of manufacturing a semiconductor device according to claim 1 or claim 2, further comprising:
forming well in the low-voltage driving transistor forming region and the MNOS type memory transistor forming region before the first gate insulating layer is formed.

5. The method of manufacturing a semiconductor device according to claim 1 or claim 2, further comprising:
forming well in the low-voltage driving transistor forming region and the MNOS type memory transistor forming region after the first gate insulating layer is formed.

6. The method of manufacturing a semiconductor device according to claim 1 or claim 2, further comprising:
forming an isolation region in the high-breakdown-voltage transistor forming region by a Local Oxidation of Silicon (LOCOS) method; and
forming an isolation region in the low-voltage driving transistor forming region and the MNOS type memory transistor forming region by a trench isolation method.

7. The method of manufacturing a semiconductor device according to claim 6, wherein the well is formed in the low-voltage driving transistor forming region and the MNOS type memory transistor forming region before the isolation region is formed in the low-voltage driving transistor forming region and the MNOS type memory transistor forming region.

8. The method of manufacturing a semiconductor device according to claim 6, wherein the well is formed in the low-voltage driving transistor forming region and the MNOS type memory transistor forming region after the isolation region is formed in the low-voltage driving transistor forming region and the MNOS type memory transistor forming region.

9. The method of manufacturing a semiconductor device according to any one of claim 1, 2, 7, or 8, wherein the high-breakdown-voltage transistor is formed to have an offset insulating layer.

10. The method of manufacturing a semiconductor device according to claim 9, wherein the offset insulating layer is formed by a LOCOS method.

11. The method of manufacturing a semiconductor device according to claim 3, further comprising:
forming well in the low-voltage driving transistor forming region and the MNOS type memory transistor forming region before the first gate insulating layer is formed.

12. The method of manufacturing a semiconductor device according to claim 3, further comprising:
forming well in the low-voltage driving transistor forming region and the MNOS type memory transistor forming region after the first gate insulating layer is formed.

13. The method of manufacturing a semiconductor device according to claim 3, further comprising:
forming an isolation region in the high-breakdown-voltage transistor forming region by a Local Oxidation of Silicon (LOCOS) method; and
forming an isolation region in the low-voltage driving transistor forming region and the MNOS type memory transistor forming region by a trench isolation method.

14. The method of manufacturing a semiconductor device according to claim 4, further comprising:
forming an isolation region in the high-breakdown-voltage transistor forming region by a Local Oxidation of Silicon (LOCOS) method; and
forming an isolation region in the low-voltage driving transistor forming region and the MNOS type memory transistor forming region by a trench isolation method.

15. The method of manufacturing a semiconductor device according to claim 5, further comprising:
forming an isolation region in the high-breakdown-voltage transistor forming region by a Local Oxidation of Silicon (LOCOS) method; and
forming an isolation region in the low-voltage driving transistor forming region and the MNOS type memory transistor forming region by a trench isolation method.

16. The method of manufacturing a semiconductor device according to claim 3, wherein the high-breakdown-voltage transistor is formed to have an offset insulating layer.

17. The method of manufacturing a semiconductor device according to claim 4, wherein the high-breakdown-voltage transistor is formed to have an offset insulating layer.

18. The method of manufacturing a semiconductor device according to claim 5, wherein the high-breakdown-voltage transistor is formed to have an offset insulating layer.

19. The method of manufacturing a semiconductor device according to claim 6, wherein the high-breakdown-voltage transistor is formed to have an offset insulating layer.

20. A method of manufacturing a semiconductor device having a high-breakdown-voltage transistor, a low-voltage driving transistor and a Metal-Oxide-Nitride-Oxide-Semiconductor (MONOS) type memory transistor, comprising:
forming a stack film that includes at least an oxide silicon layer and a nitride silicon layer over a high-breakdown-voltage transistor forming region where the high-breakdown-voltage transistor is formed, a low-voltage driving transistor forming region where the low-voltage driving transistor is formed and a MONOS type memory transistor forming region where the MONOS type memory transistor is formed in a semiconductor layer;
removing the stack film formed in a first gate insulating layer forming region of the high-breakdown-voltage transistor;
forming a first gate insulating layer in the high-breakdown-voltage transistor forming region by thermal oxidation;
removing the stack film formed in the low-voltage driving transistor forming region;
forming a second gate insulating layer in the low-voltage driving transistor forming region;
forming gate electrodes in the high-breakdown-voltage transistor forming region, the low-voltage driving transistor forming region and the MONOS type memory transistor forming region; and
forming source/drain regions in the high-breakdown-voltage transistor forming region, the low-voltage driving transistor forming region and the MONOS type memory transistor forming region.

21. The method of manufacturing a semiconductor device according to claim 9, wherein the offset insulating layer is formed by one of a semi-recess LOCOS method and a recess LOCOS method.
